(19) United States
(12) Patent Application Publication
(10) Pub. No.: US 2024/0060611 A1
(43) Pub. Date: Feb. 22, 2024

(54) RECHARGEABLE BATTERY UNIT

(71) Applicant: Wom-Batt Pty Ltd, Maroochydore, Queensland (AU)

(72) Inventor: Scott Graham LEISHMAN, Queensland (AU)

(21) Appl. No.: 18/259,269

(22) PCT Filed: Dec. 22, 2021
(86) PCT No.: PCT/AU2021/051539

§ 371 Date: Jun. 23, 2023

(30) Foreign Application Priority Data
Dec. 24, 2020 (AU) 2020104309

(51) Int. Cl. F21S 9/03; F21S 8/08; H01M 50/24; H01M 50/271; H01M 50/258; H01M 50/209; H01M 50/244

(52) U.S. Cl. CPC F21S 9/035; F21S 8/086; H01M 50/24; H01M 50/271; H01M 50/258; H01M 50/209; H01M 50/244

(57) ABSTRACT

A rechargeable battery unit for powering a street-side electrical utility such as a street lamp, the unit having a substantially cylindrical shape and being connected to a solar array, the battery unit further comprising a housing for rendering the unit water tight so that it may be located underground proximate the electrical utility.

### TECHNICAL FIELD

Embodiments relate to a battery casing, a battery unit and a method of installing a battery unit.

### BACKGROUND

Traditional street lighting and other street-side electrical utilities have required electrical power provided mains connections to operate. Where the location for the provision of this lighting or other utility is remote, the provision of a mains electrical connection can be prohibitively expensive with the result that remote streets may be more dangerous and less accessible.

With the advent of more efficient ways of converting light energy into electrical energy, solar-powered street side electrical lighting and utilities have become possible. However, using solar power for such applications has a number of disadvantages.

Due to the power requirements of, for example, street-side lighting and the requirement that such lighting operate at night, even after overcast days, the batteries used to operate each light need to have significant capacity, for example up to 800 amp hours. This, in turn, means that the batteries can be heavy. So, for low power applications such as speed compliance signage, it is possible to locate the battery, solar cells and the electrical components for the sign at the top of a pole which also supports the sign.

However, for lighting and other applications, the weight of the battery may be too large to be supported by standard poles. It may therefore be necessary to store such batteries near the base of the pole, but this may create a security problem since such batteries are valuable, and are therefore subject to theft. It is therefore desirable to secure these batteries.

Certain applications make use of a secured road-side storage bin, but this may create a safety concern for motorists and other road users since the reinforcement may provide a significant impact in the case of accident. Furthermore, such bins are exposed to direct sunlight and may lack adequate ventilation, exposing the batteries to extreme temperatures.

Furthermore, it is not possible to bury certain kinds of batteries such as lead acid batteries since they emit gas over their lifecycle.

### SUMMARY OF THE DISCLOSURE

An embodiment extends to a rechargeable battery unit comprising a housing and a plurality of battery cells located within the housing, wherein the housing has a substantially round or oval cross-section.

The housing may be elongate.

The housing may be substantially cylindrical in shape.

The housing may be substantially round-cylindrical in shape.

The housing may have a length of more than 30 cm. In an embodiment, the length is less than 2 meters. The diameter may be between 30 cm and 60 cm.

The housing may comprise a skeleton. The skeleton may comprise a plurality of elongate members running a length of the housing. The housing may have a top and a bottom and the elongate members may run from substantially the top to substantially the bottom of the housing. The skeleton may comprise one or more plate members. The elongate members may be tubes or bars.

One or more of the plurality of battery cells may be rectangular cuboid in shape. The plurality of battery cells may be provided in one or more cell units. There may be two or more cell units, each cell unit comprising a plurality of cells.

One or more of the battery cells may be lithium ion batteries. The one or more battery cells may be lithium iron phosphate batteries (LiFePO4). In an embodiment all of the battery cells are lithium ion batteries.

The battery unit may comprise one or more modular units. Where there is more than one modular unit, the modular units may be stacked vertically. A modular unit may comprise a cell unit, a plate member to separate adjacent cell units and at least one cell spacer for separating adjacent cell units.

Each cell unit may comprise a plurality of battery cells. In an embodiment, each cell unit has the same number of battery cells.

Each modular unit may comprise two cell spacers. The cell spacers may engage with the elongate members.

Each modular unit may be connected to one or more elongate members running a length of the housing.

A cell unit may comprise a single battery cell or a plurality of battery cells connected together.

The housing may be water-tight. The housing comprises a base unit and a cover, the base unit being attached to the base unit to form a water-tight seal. The housing may be water tight to the IP 68 specification.

The housing may be comprised of steel. The steel may be stainless steel of 316 or 304 variety.

The housing may have a valve. The housing may have a pressure release valve.

The housing may have a cover over the valve.

The housing may comprise a level to determine when the battery unit is correctly orientated.

The level may be integrated into the housing. The level may be integrated into the cover for the valve. The level may be a bubble degree level.

A further embodiment extends to a battery unit for powering a street-side electrical utility such as a street lamp, the unit having a substantially cylindrical shape and being connected to a solar array, the battery unit further comprising a housing for rendering the unit water tight so that it may be located underground proximate the electrical utility.

A further embodiment extends to an electrical installation comprising a road-side utility mounted to a pole, the pole being suitable for location next to a street, a hole formed proximate the pole and a battery unit as herein described located in the hole and connected to the utility and an array of solar cells.

By locating the battery underground, embodiments may provide a number of advantages. For example, the temperature variations of the battery may be less extreme compared to a battery stored in a road-side storage bin, and this may increase the life span of the battery. Furthermore, the location of the battery may be more easily hidden, potentially making it harder for thieves to locate the battery. By locating the battery underground, the potential danger posed by a road-side security bin may be removed.

A further embodiment relates to a method of installing a rechargeable battery unit, the method comprising:
forming a substantially cylindrical hole and placing the battery unit in the hole.

The battery unit may be for powering a utility mounted on a pole and the hole may be formed proximate the pole.

The method may further comprise at least partially filling the hole with drainage aggregate. The drainage aggregate may surround the battery unit and may therefore be added after the battery unit has been placed in the hole.

The hole may be at least partially filled with earth. The earth may comprise material removed from the hole. The earth may be placed on top of the aggregate.

The utility may be a street-side electrical utility and be street lighting. In a further embodiment the utility may be one or more of lighting, weather stations, rain sensors, camera, illuminated signs, safety signs, speed signs, warning signs and systems, proximity sensors, impact sensors, electric fences, remote alarm systems. The utility may be mounted to a pole and the hole may be formed in proximity to the pole.

The method may further comprise covering the battery unit once installed in the hole and then covering the hole with backfill or other material which allows the passage and disbursement of water.

The hole may be formed by an auger. In an embodiment, the battery unit has a maximum diameter less than 400 mm. In certain applications, a standard auger size is 450 mm used for footings for certain road-side utilities. Therefore, providing a battery unit with this size may avoid the need to change tools when forming the hole for the battery unit.

The battery unit may be substantially as described.

### DESCRIPTION OF THE DRAWINGS

Embodiments are herein described, with reference to the accompanying drawings in which:

FIG. 1 is a schematic view of a street light installation incorporating a battery unit according to an embodiment;

FIG. 2 is front perspective view of a battery unit according to an embodiment;

FIG. 3 is a front perspective view of a skeleton of the battery unit of FIG. 2;

FIG. 4 is a side perspective view of the skeleton of FIG. 3 with battery cells installed therein;

FIG. 5 is a perspective view of a battery pack for use with the battery unit of FIG. 2;

FIGS. 6 to 7 illustrate details of a battery unit according to a further embodiment;

FIGS. 8 and 9 illustrate components for use with the battery unit of FIGS. 6 and 7;

FIGS. 10 and 11 illustrate details of a battery unit according to a further embodiment; and

FIGS. 12 and 13 illustrate details of a battery unit according to a further embodiment of the invention.

### DETAILED DESCRIPTION OF SPECIFIC EMBODIMENT

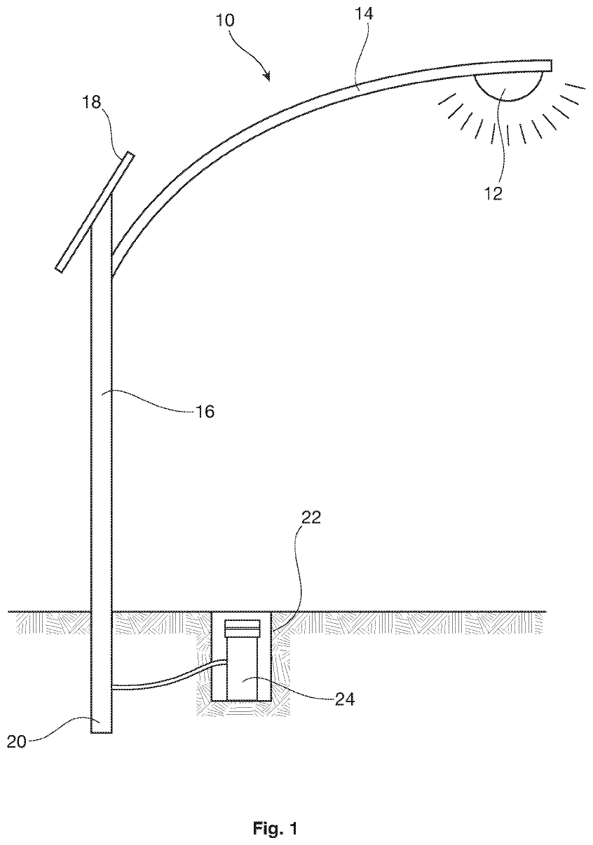

FIG. 1 illustrates a street light installation 10 comprising a light 12 mounted on a boom of a pole 16. The pole 16 carries a solar cell array 18 and is located in the ground by a concrete pre-case 20. A further hole 22 is formed in the ground in the manner described below, and a battery unit or pod 24 is located in the hole 22.

The battery unit 24 is connected to the light 12 and the solar cell array 18 in a known manner and these electrical connections, and the corresponding electrical operations, of these units will not be further described herein.

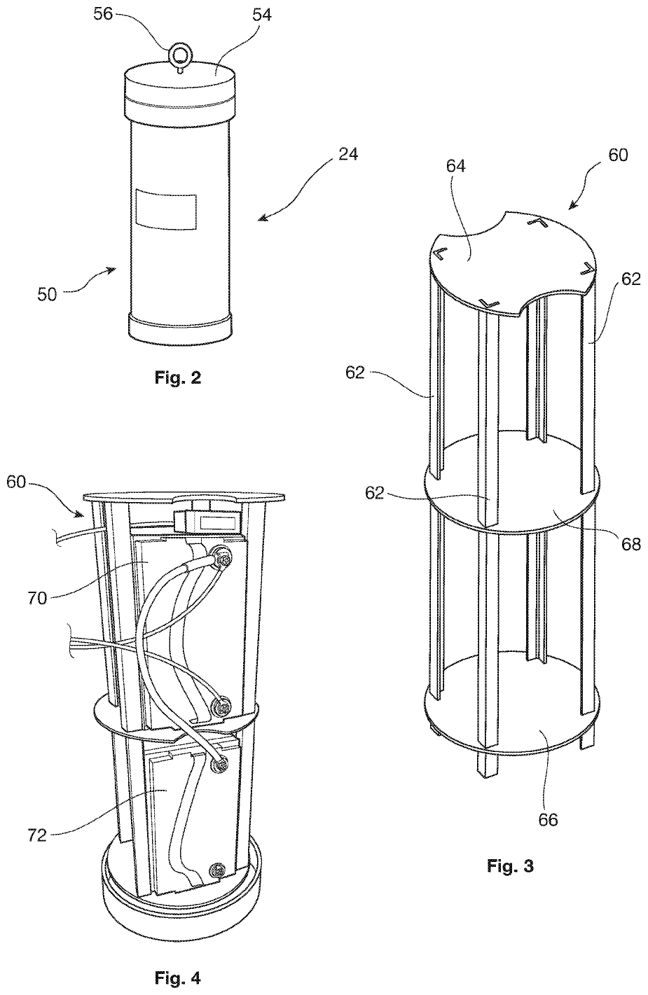

The battery unit 24 is illustrated in further detail in FIG. 2. The battery unit 24 comprises a housing 50 having a base 52 and a cap 54. A loop 56 is attached to the cap 54 and provides a convenient attachment for lifting and moving the battery unit 24.

As illustrated in FIG. 2, the battery is cylindrical in shape and this cylinder is formed by a round cap 54 which fits on top of the cylindrical, hollow base 52. Preferably, the cap 54 has a substantially water tight fitting with the base 52 to prevent ingress of water into the battery unit which would affect the electronic operation of the unit 24. In this embodiment, the cap 54 and base 52 have been bolted together (not shown), but other suitable fittings may be used instead.

FIG. 3 illustrates a skeleton 60 which fits inside the housing 50 shown in FIG. 2. The skeleton 60 is comprised of a plurality of elongate square-section rods 62 attached to a top plate 64, middle plate 68 and base plate 66. The top plate 64, middle plate 68 and base plate 66 are round and are dimensioned to fit into the housing 50 with low manufacturing tolerances. A relatively good fit between these plates and the housing may help to avoid movement of the battery units, which are secured in place by the skeleton, relative to the housing, in particular during transport and installation of the battery unit 24.

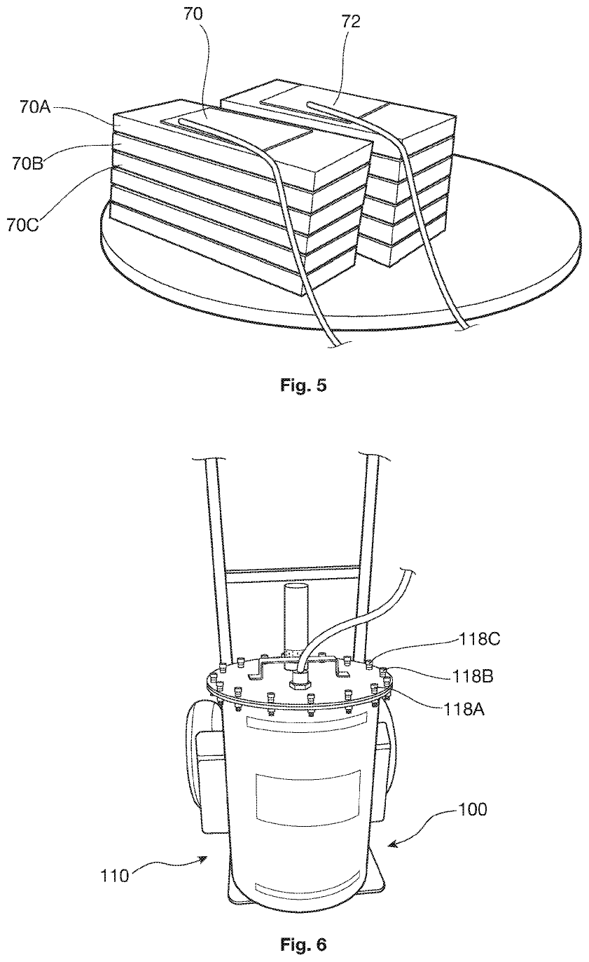

FIG. 4 illustrates the skeleton 60 with two battery packs 70 and 72 installed therein. As illustrated in FIG. 3, the space between the middle plate 68 and the top plate 64 forms a space for a first battery pack 70 and the space between the middle plate 68 and the bottom plate 66 forms a space for the second battery pack 72. The battery packs 70 and 72 are mechanically attached to the skeleton 60. It is to be realised that different forms of mechanical attachment are possible. In certain embodiments, other suitable forms of attachment may be used instead or, or as well as, mechanical attachment.

FIG. 5 illustrates the two battery pack 70 and 72 in greater detail. As illustrated, each battery back is made up of a number of battery cells. For example, battery pack 70 is made up of battery cells 70A, 70B, 70C etc. Battery pack 72 has a similar construction. In this embodiment, each of the battery packs 70 and 72 are made up of six cells, but is to be realised that more or fewer cells could be used instead.

In this embodiment, the battery cells are prismatic (i.e. shaped as a rectangular cuboid). Having prismatic cells may provide for easier connection between cells and a greater energy density than other shapes for the cells such as cylindrical. It is to be realised that the dimensions of the overall battery unit 24 (FIGS. 1 and 2) is too large for provision of a single cell, particular in the case where lithium ion batteries are used.

In this embodiment, all of the battery cells 70A, 70B, . . . are lithium ion batteries. It is to realised that in an embodiment, the cells illustrated by be battery packs comprised of a number of interconnected cells.

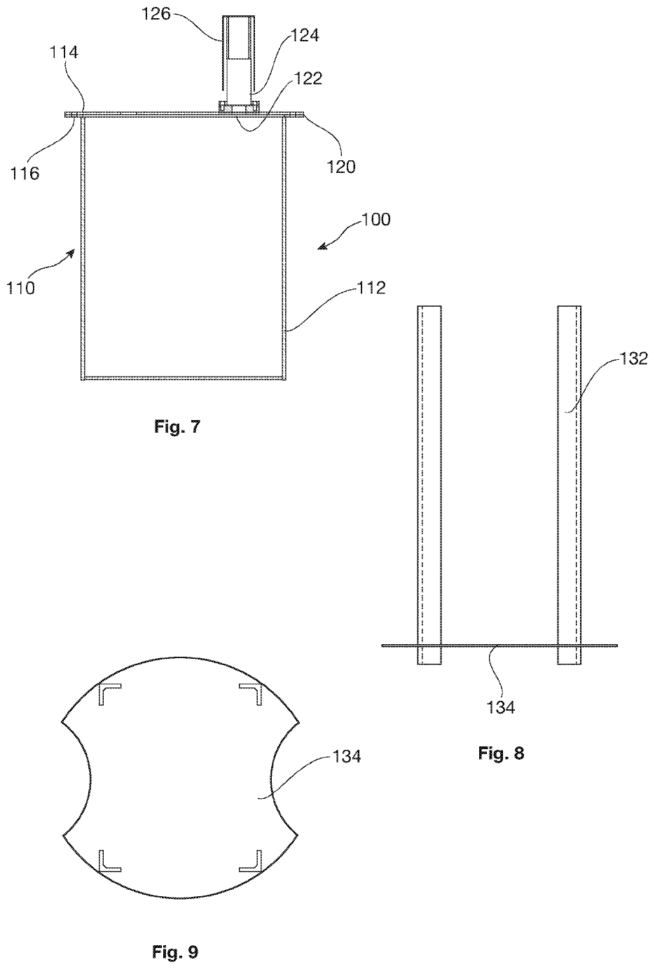

FIGS. 6 and 7 illustrate a battery unit 100 according to a further embodiment. The battery unit 100 has the same internal structure as the battery unit 24 illustrated in FIGS. 1 to 5. The battery unit 100 differs from the battery unit 24 in that the battery unit 100 has a housing 110 comprising a hollow cylindrical base unit 112 and a cap 114. The base unit 112 has a flange 116 which engages with the cap 114 and the two are bolted together by bolts 118A, 118B, 118C, . . . .

A gasket 120 is situated between the base unit 112 and cap 114 so that the bolts 118A, 118B, 118C, . . . which attach the two together form a seal. In this embodiment, the seal provides a water-tight housing for the battery cells. However, a potential disadvantage is that any fluid which may form in the housing (in the unlikely event of fire, for example) may be unable to escape.

For this reason, the cap 114 includes a port 122 which is surrounded by a perforated tube 124. The perforated tube 124 has a solid tube 126 situated over it and which acts as a dust cover to reduce the ingress of dust and gravel into the enclosure formed around the port 122.

A pressure valve (not shown) is located in the port 122 and if the pressure in the housing 110 exceeds a predetermined amount due, for example smoke being released due to a short circuit on over-charged cells, the pressure valve will operate to reduce the pressure, thereby avoiding an explosive release.

The cap 114, perforated tube 124, solid tube 126 and valve form a valve assembly.

FIG. 8 illustrates a skeleton 130 for use with the housing 110 of FIG. 7. As with the skeleton 60 illustrated in FIG. 3, the skeleton 130 is used to carry and protect the battery units which are installed into the housing 110 to form the battery unit 110. The skeleton 130 comprises elongate bars 132 attached to a base plate 134. The base plate 134 is shown in greater detail in FIG. 9.

The battery units 24 and 100 are installed by forming a cylindrical hole 22 in the ground proximate to the pole 16 carrying the utility (in this case light 12) to be powered by the unit (see FIG. 1). Since the units are cylindrical, they fit well into a cylindrical hole. In an embodiment, the cylindrical hole may be formed by an auger which may be significantly cheaper and quicker than digging a rectangular or square pit.

The unit is then lifted into place, being situated with the cylindrical hole, connected electronically to the light 12 and solar cell array 18 and the hole is then filled with course backfill which allows pressure to escape, if required. It has been found that a drainage aggregate may work well. The aggregate is then covered with soil.

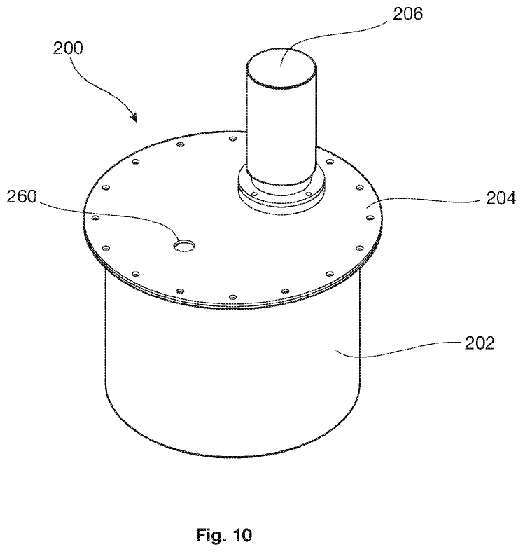

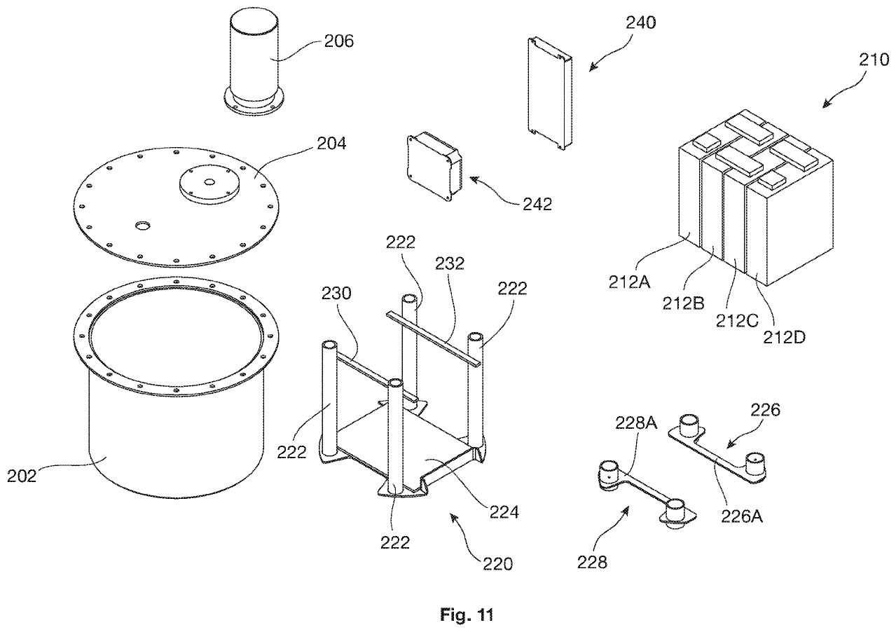

FIGS. 10 and 11 illustrate a battery unit according to a further embodiment. The battery unit 200 comprises a cylindrical base unit 202 covered by a cap 204. A valve assembly 206 is attached to the cap. The valve assembly is as described above with reference to FIGS. 8 and 9.

FIG. 11 is an exploded view of the various components which make up the battery unit 200. The battery unit 200 comprises a cell unit 210 made up of four interconnected battery cells, 212A, 212B, 212C and 212D.

A skeleton 220 includes four elongate tubes 222, each connected to base plate 224. Two cell spacers 226 and 228 are also provided.

The battery unit 200 is assembled by locating the cell unit 210 on the base plate 224 and the cell spacers 224 and 226 are then located over the elongate tubes 222. As illustrated, each spacer is formed with a respective ledge 226A and 228A which, once installed, will rest on an upper surface of the cell unit 210. Two foam strips 230 and 232 are provided to prevent a short circuit between the cell unit 210 and the spacers 226 and 228.

Control electronics in the form of a battery management system 240 and charge controller 242 are then attached to the spacers 226 and 228. The assembly is then placed inside the cylindrical base unit 202, and the cap 204 and valve assembly 206 are then attached to the base unit 202. In order to maintain the required level of seal, a rubber gasket (not shown) is provided between the cap and the flange defining the upper end of the cylindrical base unit. As illustrated, in this embodiment, the cap and base unit are attached to one another with 16 bolts (the holes through which these bolts pass are shown). It has been found that the number of bolts may influence the water-tight properties of the unit. Although certain embodiments may use 16 bolts, it is to be realised that this may, to a certain extent, be a function of the size of the cap and base unit. In further embodiments, at least 10 bolts may be used. So too, a cable gland may be provided for the electrical cable which exits the cap.

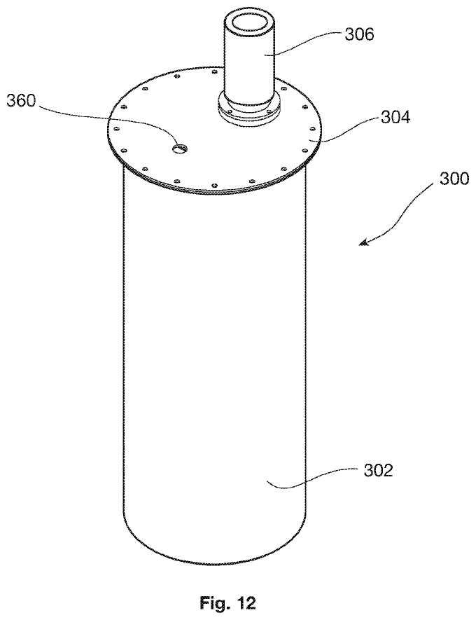

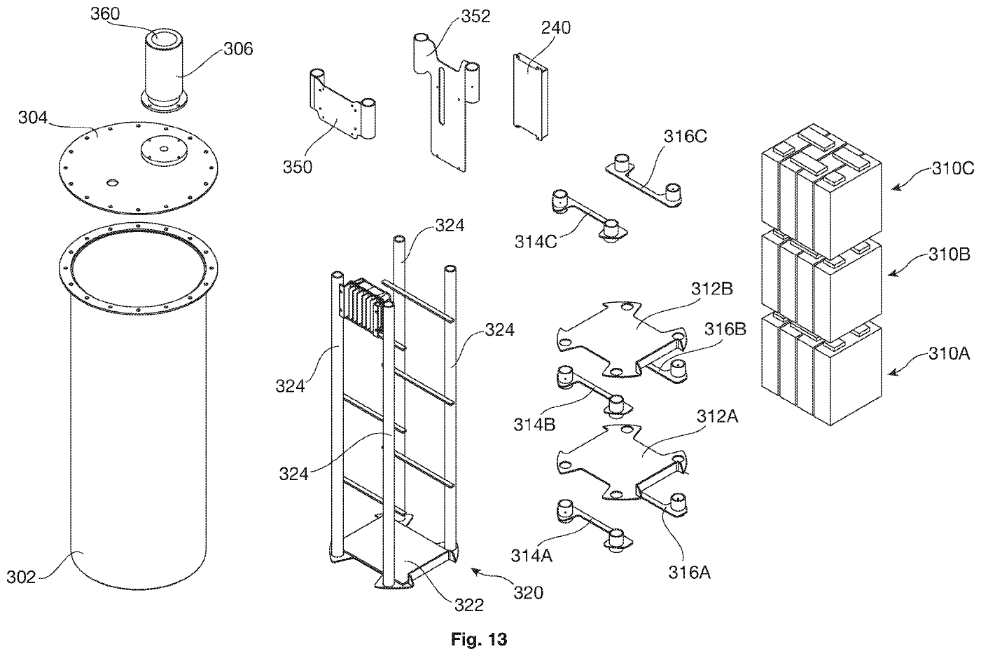

FIGS. 12 and 13 illustrate a battery unit 300 according to a further embodiment. The battery unit 300 comprises a cylindrical base unit 302 covered by a cap 304. A valve assembly 306 is attached to the cap. The valve assembly 306 is as described above with reference to FIGS. 8 and 9.

FIG. 13 is an exploded view of the various components which make up the battery unit 300. The battery unit 300 is constructed in a modular fashion with each module composed substantially as a portion of battery unit 200 illustrated in FIGS. 10 and 11.

A skeleton 320 in the form of base plate 322 and elongate rods 324 is provided. Furthermore, three cell units 310A, 310B and 310C are provided together with two separating plates 312A and 312B. Three sets of two cell spacers are also provided, 314A, 316A; 314B, 316B; and 314C, 316C.

Each module is then comprised of a plate (the lowermost module using the base plate 322), a cell unit and two cell spacers. For example, the topmost module comprises plate 312B, cell unit 310C and spacers 314C and 316C.

It can be seen that the battery unit 200 illustrated in FIGS. 10 and 11 is therefore a single module. By providing a modular structure battery units with different capacity may be constructed quickly and easily using similar parts.

Referring back to FIG. 13, two brackets 350 and 352 engage with adjacent rods 324 to mount the battery management system 240 and charge controller 242.

Once the modular units and other components have been mounted to the skeleton 320, this is placed inside the circular base unit 302 and the cap 304 and valve assembly 306 are attached. The embodiment of FIGS. 10 and 11 comprises a cable port 260 formed in the cap 204 and the embodiment of FIGS. 12 and 13 comprises a cable port 360 formed in the cap 304. Both cable ports 260 and 360 provide for a hole through which electrical cables pass to provide an electrical path between the rechargeable batteries contained within the respective units and the street-side utility to which they are connected. As referred to above, a cable gland is provided to prevent the ingress of water into the housing. In addition, the end of the cables may be resin potted.

The battery unit 300 illustrated in FIG. 13 includes a bubble spirit level 360 attached to the top of the valve assembly 306. In this embodiment, the bubble spirit level is a two-axis spirit level which allows a user to level the battery unit 300 when it is being installed. In this embodiment, the level is provided at the top of the cap since this is the highest point of the unit. However, in other embodiments, the level may be located elsewhere. For example, it may be desirable to use a larger level, in which case the level may be located on the upper surface of the cover 304.

It is to be realised that in certain embodiments relating to installation of a battery unit that there may be certain advantages to forming a cylindrical hole and that the unit need not be cylindrical to fit into the hole, provided that the unit and the hole have been dimensioned accordingly.

As used herein, the term “device” shall not be limited to meaning a unitary entity, but covers both a unitary entity and an entity comprising distinct components whether manually removable, or not.

It is to be understood that, if any prior art publication is referred to herein, such reference does not constitute an admission that the publication forms a part of the common general knowledge in the art, in Australia or any other country.

In the claims which follow and in the preceding description, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments. Similarly, the word “device” is used in a broad sense and is intended to cover the constituent parts provided as an integral whole as well as an instantiation where one or more of the constituent parts are provided separate to one another.

1-9. (canceled)

10. A method of installing a rechargeable battery unit, the method comprising:
forming a substantially cylindrical hole in the ground and placing the battery unit in the hole.

11. The method according to claim 10 wherein the battery unit is for powering a utility mounted on a pole and the hole is formed proximate the pole.

12. The method according to claim 10 further comprising at least partially filling the hole with drainage aggregate after the battery unit has been placed in the hole.

13. The method according to claim 12 further comprising placing earth on top of the aggregate.

14. The method according to claim 10 wherein the rechargeable battery unit comprises a housing and a plurality of battery cells located within the housing, wherein the housing has a substantially round or oval cross-section.

15. (canceled)

16. The method according to claim 14 wherein the housing is substantially elongate and round-cylindrical in shape.

17. The method according to claim 16 wherein the rechargeable battery unit comprises a skeleton having a plurality of elongate members running a length of the housing, the elongate members being attached to one or more circumferential members.

18. The method according to claim 14 wherein the rechargeable battery unit comprises one or more modular units, each modular unit comprising a cell unit, a plate member to separate adjacent cell units and at least one cell spacer for separating adjacent cell units, wherein the plurality of battery cells are provided as the cell units, each cell unit comprising a plurality of battery cells.

19. The method according to claim 17 wherein each modular unit comprises two cell spacers, wherein each cell spacer is adapted to engage with two adjacent elongate members.

20. The method according to claim 18 wherein the rechargeable battery unit comprises a plurality of modular units arranged vertically.

21. The method according to claim 14 wherein the rechargeable battery unit further comprises a port formed in the housing and a valve assembly connected to the port wherein the valve assembly comprises a pressure valve and a cover for covering the valve.

22. The method according to claim 14 wherein the housing of the rechargeable battery unit comprises a level.

23. The method according to claim 14 wherein the housing of the rechargeable battery unit comprises a base unit and a cover, the base unit being attached to the base unit to form a water-tight seal.

24. An electrical installation comprising a road-side utility mounted to a pole, the pole being suitable for location next to a street, a hole formed in the ground proximate the pole and a battery unit located in the hole and connected to the road-side utility and an array of solar cells, wherein the hole and the batter are both cylindrical.

25. A rechargeable battery unit comprising a housing and a plurality of battery cells located within the housing, wherein the housing has a substantially round or oval cross-section.

26. The rechargeable battery unit according to claim 25 wherein the housing is substantially elongate and round-cylindrical in shape.

27. The rechargeable battery unit according to claim 25 further comprising a skeleton having a plurality of elongate members running a length of the housing, the elongate members being attached to one or more circumferential members.

28. The rechargeable battery unit according claim 25 comprising one or more modular units, each modular unit comprising a cell unit, a plate member to separate adjacent cell units and at least one cell spacer for separating adjacent cell units, wherein the plurality of battery cells are provided as the cell units, each cell unit comprising a plurality of battery cells.

29. The rechargeable battery unit according to claim 25 further comprising a port formed in the housing and a valve assembly connected to the port wherein the valve assembly comprises a pressure valve and a cover for covering the valve.

30. The rechargeable battery unit according to claim 24 wherein the housing further comprises a level.

31. The rechargeable battery unit according to claim 24 wherein the housing comprises a base unit and a cover, the base unit being attached to the base unit to form a water-tight seal.
